(19) United States
(12) Patent Application Publication
(10) Pub. No.: US 2014/0218115 A1
(43) Pub. Date: Aug. 7, 2014

(54) CURRENT COMPENSATION CIRCUIT, METHOD AND OPERATIONAL AMPLIFIER

(71) Applicants: Lei Huang, Beijing (CN); Na Meng, Beijing (CN)

(72) Inventors: Lei Huang, Beijing (CN); Na Meng, Beijing (CN)

(21) Appl. No.: 14/173,647

(22) Filed: Feb. 5, 2014

(30) Foreign Application Priority Data
Feb. 5, 2013 (CN) 201310050993.9

(51) Int. Cl. H02M 3/04; H03F 1/30; H03F 3/45

(52) U.S. Cl. CPC H02M 3/04; H03F 3/45071; H03F 1/301
USPC 330/261; 327/538

(57) ABSTRACT

Disclosed is a current compensation circuit. During calibration of a compensation current, a digital control circuit delivers a digital signal with values varying over time to a current compensation array, the current compensation array outputs different amounts of compensation current based on the digital signal with values varying over time, the digital control circuit latches a value of the digital signal, which results in a best compensation current, based on influences of the different amounts of compensation current on a parameter to be calibrated, to complete the calibration. Upon and after completion of the calibration, the digital control circuit continuously delivers the digital signal with the latched value to the current compensation array, and the current compensation array outputs the best compensation current based on the digital signal with the latched value.

### CLAIM OF PRIORITY

This application claims the benefit of priority under 35 U.S.C. §119 to Chinese Patent Application Serial No. 201310050993.9, filed Feb. 5, 2013, which is incorporated herein by reference in its entirety.

### TECHNICAL FIELD

Among others, the disclosure relates to current compensation technologies for integrated circuits, and particularly to a current compensation circuit, method and an operational amplifier.

### BACKGROUND

It is desired that an operational amplifier would have an input offset voltage of zero volt. However, in practice, it is very difficult to manufacture an operational amplifier with a differential input stage having symmetric inputs. In a manufacturing process, it is difficult to ensure that both metal-oxide-semiconductor type field effect transistors (MOS) at the differential input stage are totally the same. Generally, after an operational amplifier is connected as a follower having a gain of 0 dB, the input voltage would not be equal to zero, and thus is referred to as an offset voltage (Voffset).

Generally, current compensation is performed at the differential input stage of the operational amplifier to decrease the offset voltage thereof However, due to uncertainty of the offset voltage of a particular operational amplifier (e.g., even operational amplifiers from a same company or in a same batch may have offset voltages with different values and even different polarities (positive or negative)), it would be infeasible to perform compensation by a fixed approach.

### OVERVIEW

In an example, a current compensation circuit is provided, which includes a digital control circuit and a current compensation array. The digital control circuit is configured to: during calibration of a compensation current, deliver a digital signal with values varying over time to the current compensation array, and latch a value of the digital signal, which results in a best compensation current, based on influences of different amounts of compensation current on a parameter to be calibrated, to complete the calibration; and upon and after completion of the calibration, continuously deliver a digital signal with the latched value to the current compensation array. The current compensation array is configured to: during calibration of the compensation current, output the different amounts of compensation current based on the digital signals with values varying over time; and upon completion of the calibration, output the best compensation current based on the digital signal with the latched value.

In an example, an operational amplifier is provided, which includes an input stage circuit, a gain stage circuit, an output stage circuit, a two-way switch and a current compensation circuit. The input stage circuit is configured to: connect positive and negative inputs of the operational amplifier to ground, when the operational amplifier starts to operate; and receive a positive input signal at the positive input and a negative input signal at the negative input, upon reception of a disconnection signal from the current compensation circuit. The gain stage circuit is configured to connect an positive or negative input of the gain stage circuit to an output of the current compensation circuit, and connect an output of the gain stage circuit to the two-way switch. The two-way switch is configured to: allow the output of the gain stage circuit to be connected to a detection terminal of the current compensation circuit, when the operational amplifier starts to operate; and allow the output of the gain stage circuit to be connected to an input of the output stage circuit, upon reception of a disconnection signal from the current compensation circuit. The output stage circuit is configured to send out an output signal. The current compensation circuit is configured to: during calibration of a compensation current, generate a digital signal with values varying over time to output different amounts of the compensation current, latch a value of the digital signal, which results in a best compensation current, based on influences of the different amounts of compensation current on a parameter to be calibrated, to complete the calibration; and upon and after completion of the calibration, output the best compensation current based on the digital signal with the latched value, and send the disconnection signal to the input stage circuit and the two-way switch.

In an example, a current compensation method is provided, in which during calibration of a compensation current, a digital signal with values varying over time is generated to output different amounts of compensation current, a value of the digital signal, which results in a best compensation current, is latched based on influences of the different amounts of compensation current on a parameter to be calibrated, to complete the calibration; and upon and after completion of the calibration, the best compensation current is output based on the digital signal with the latched value.

According to the current compensation circuit and method and operational amplifier of the disclosure, in the current compensation circuit, during calibration of a compensation current, the digital control circuit delivers a digital signal with values varying over time to the current compensation array; the current compensation array outputs different amounts of compensation current based on the digital signal with values varying over time; the digital control circuit latches a value of the digital signal, which results in a best compensation current, based on influences of the different amounts of compensation current on a parameter to be calibrated, to complete the calibration; and upon and after completion of the calibration, the digital control circuit continuously delivers the digital signal with the latched value to the current compensation array, and the current compensation array outputs the best compensation current based on the digital signal with the latched value. In this way, regardless of the amount of compensation current required for the parameter to be calibrated, the current compensation circuit is able to provide the best compensation current accurately and rapidly. When the current compensation circuit is applied to the operational amplifier, it can individually compensate the offset value for each operational amplifier, and thus the accuracy of the operational amplifier is improved and the manufacturing process of the operational amplifier is simplified.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic diagram of a current compensation circuit according to an embodiment of the disclosure;

FIG. 2 is a schematic diagram of a current compensation circuit, in which current compensation is performed by counting using a counter, according to an embodiment of the disclosure;

FIG. 3 is a schematic diagram of the current compensation circuit, in which current compensation is performed by dichotomy, according to an embodiment of the disclosure;

FIG. 4 is a schematic diagram of a first operational amplifier according to an embodiment of the disclosure; and

FIG. 5 is a schematic diagram of a second operational amplifier according to an embodiment of the disclosure.

### DETAILED DESCRIPTION

According to various embodiments of the disclosure, during calibration of a compensation current, a digital signal with values varying over time is generated to output different amounts of compensation current, a value of the digital signal, which results in a best compensation current, is latched based on influences of the different amounts of compensation current on a parameter to be calibrated, to complete the calibration; and upon and after completion of the calibration, the best compensation current is output based on the digital signal with the latched value.

Hereinafter, the subject matter will be described in detail with reference to the drawings and the embodiments.

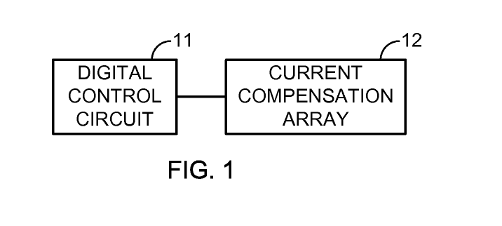

In an embodiment, a current compensation circuit is provided. As shown in FIG. 1, the current compensation circuit includes a digital control circuit 11 and a current compensation array 12. The digital control circuit 11 is configured to: during calibration of a compensation current, deliver a digital signal with values varying over time to the current compensation array 12, and latch a value of the digital signal, which results in a best compensation current, based on influences of different amounts of compensation current on a parameter to be calibrated, to complete the calibration; and upon and after completion of the calibration, continuously deliver a digital signal with the latched value to the current compensation array 12. The current compensation array 12 is configured to: during calibration of the compensation current, output the different amounts of compensation current based on the digital signals with values varying over time; and upon completion of the calibration, output the best compensation current based on the digital signal with the latched value.

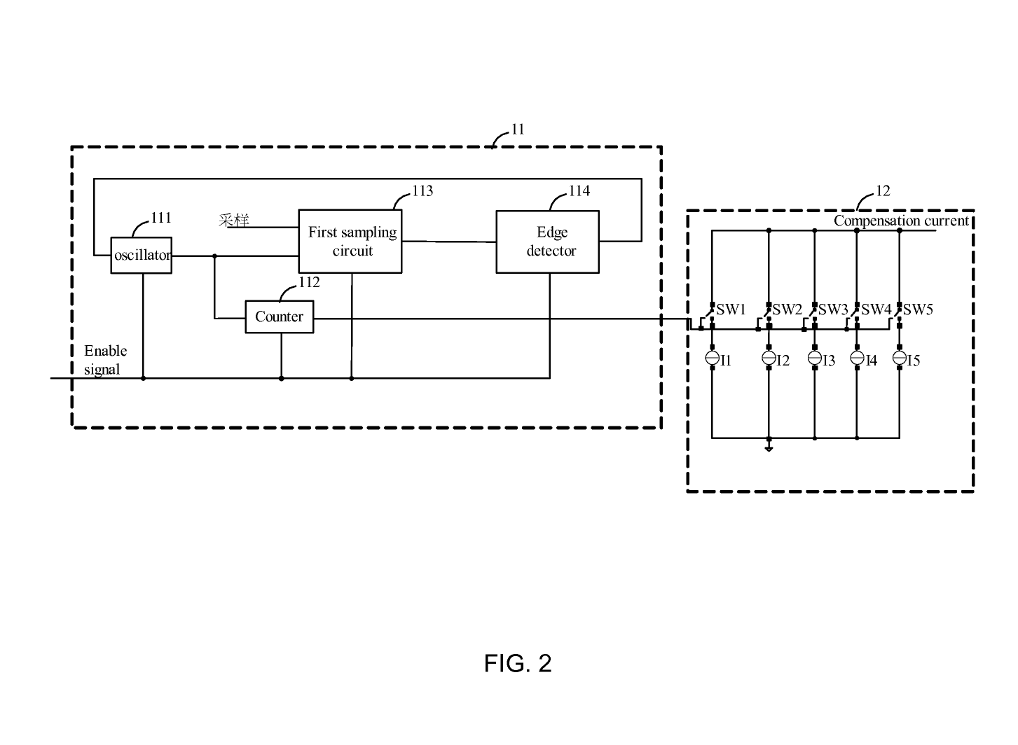

As shown in FIG. 2, in the current compensation circuit, the digital control circuit includes an oscillator 111, a counter 112, a first sampling circuit 113 and an edge detector 114. The oscillator 111 is configured to: output a clock signal; and stop outputting the clock signal upon reception of a stop signal. The counter 112 is configured to: upon reception of the clock signal, start to count cycles of the received clock signal, deliver the digital signal with values varying over time, which are equal to counted values, to the current compensation array 12; and without the clock signal being received, stop counting, and continuously deliver the digital signal with the latched value, which is equal to a final counted value, to the current compensation array 12. The first sampling circuit 113 is configured to: measure the parameter to be calibrated; and send an edge trigger signal to the edge detector 114, when an amount of the compensation current causes the parameter to be calibrated to reach a standard value. The edge detector 114 is configured to send the stop signal to the oscillator 111 upon reception of the edge trigger signal. The current compensation array 12 is configured to output the compensation current based on the digital signal with the value delivered by the counter. The current compensation array 12 consists of N parallel current compensation branches, each consisting of a current source for supplying a current and a switch serially connected to the current source, and all of the switches in the N current compensation branches are controlled by the digital signal with the value delivered by the counter 112. That is, N bits of the digital signal control the respective switches in the N current compensation branches. Here, the N current compensation branches comprise first to Nth current sources respectively, and each of the first to (N−1)th current sources supplies an amount of current that is half of that supplied by its immediate next neighbor. Generally, the first to Nth current sources in the N current compensation branches may supply currents of 20*I . . . 2N−1*I, where the current source in the current compensation branch controlled by the lowest bit supplies a current of 20*I, I is a unit current, and N is a positive integer no less than 2. In the example current compensation circuit as shown in FIG. 2, N is equal to 5, and the 5 current compensation braches includes first to fifth switches SW1 to SW5 respectively and first to fifth current sources I1 to I5.

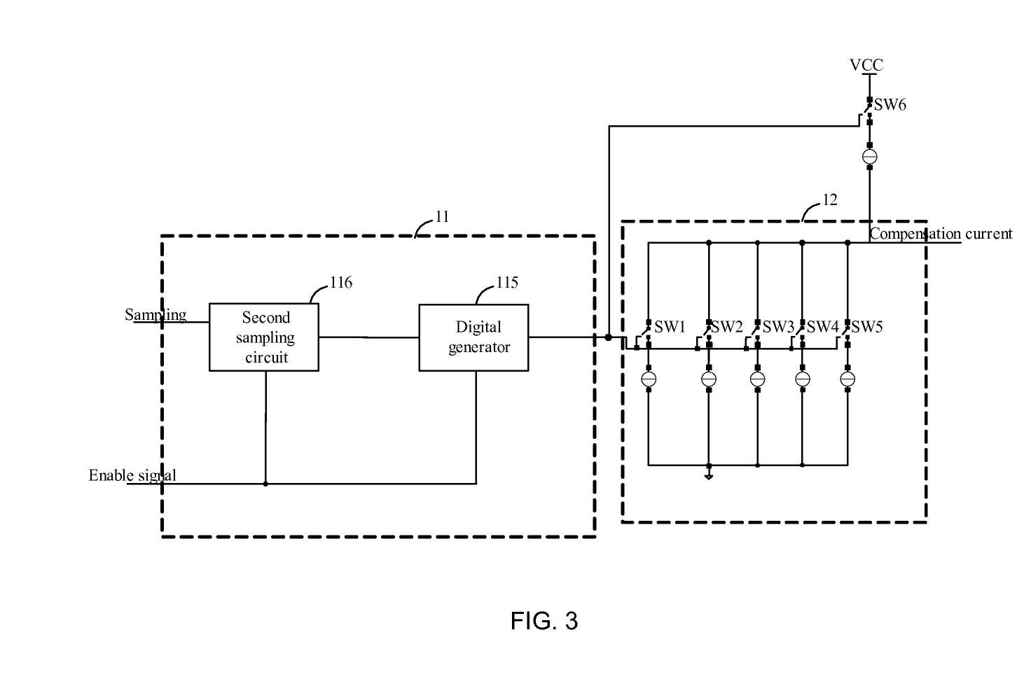

As shown in the current compensation circuit as shown in FIG. 3, the digital control circuit 11 includes a digital generator 115 and a second sampling circuit 116. The digital generator 115 is configured to: without a calibration success signal having been received from the second sampling circuit 116, deliver the digital signal with values varying over time to the current compensation array 12 by means of dichotomy; and upon reception of the calibration success signal from the second sampling circuit, latch a final value, and continuously delivering the digital signal with the latched final value to the current compensation array 12. The second sampling circuit 116 is configured to: measure the parameter to be calibrated; and send the calibration success signal to the digital generator 115 when an amount of compensation current causes the parameter to be calibrated to reach a standard value. The current compensation array 12 is configured to output the compensation current based on the digital signal with the value delivered by the digital generator. Here, the current compensation array 12 consists of N parallel current compensation branches, each consisting of a current source for supplying a current and a switch serially connected to the current source, and all of the switches in the N current compensation branches are controlled by the digital signal with the value delivered by the digital generator 115. That is, N bits of the digital signal control the respective switches in the N current compensation branches. Here, the N current compensation branches comprise first to Nth current sources respectively, and each of the first to (N−1)th current sources supplies an amount of current that is half of that supplied by its immediate next neighbor. Generally, the first to Nth current sources in the N current compensation branches may supply currents of 20*I . . . 2N−1*I, where the current source in the current compensation branch controlled by the lowest bit supplies a current of 20*I, I is a unit current, and N is a positive integer no less than 2. In the example current compensation circuit as shown in FIG. 3, assuming that SWk (k=1 . . . N, N is equal to 6) corresponds to a current of Ik, 2Ik>=Ik+1>Ik, the current compensation array 12 receives a digital signal with a value A, which is a N-bit binary number (ANAN−1 . . . A1), SWk is closed when Ak=1 and SWk is open when Ak=0. When the current compensation array 12 receives a digital signal with a value A, a corresponding compensation current I(A)=ΣAk*Ik is output. Assuming that a desired compensation current is denoted as Ios, and the corresponding closest digital signal has a value denoted as Aos, then a dichotomy heuristic procedure performed from the highest bit. That is, the digital generator 115 generates a digital signal with a value A, where AN=1 and AN−1=0; if the second sampling circuit 116 returns a calibration success signal to the digital generator 115, it indicates that A>Aos and AN should be equal to 0; otherwise, it indicates that A<Aos and AN should be equal to 1; accordingly, the digital generator 115 stores the values of AN and continues to determine the value of the next bit, AN−1 during the next clock cycle, until the value of A1 is determined; the digital generator 115 then latches the final value and continuously deliver the digital signal with the final value to the current compensation array 12. Compared with the current compensation circuit in FIG. 2, in practice, the current compensation circuit in FIG. 3 may determine the value of the digital signal corresponding to the best compensation current more rapidly, and output the best compensation current more quickly.

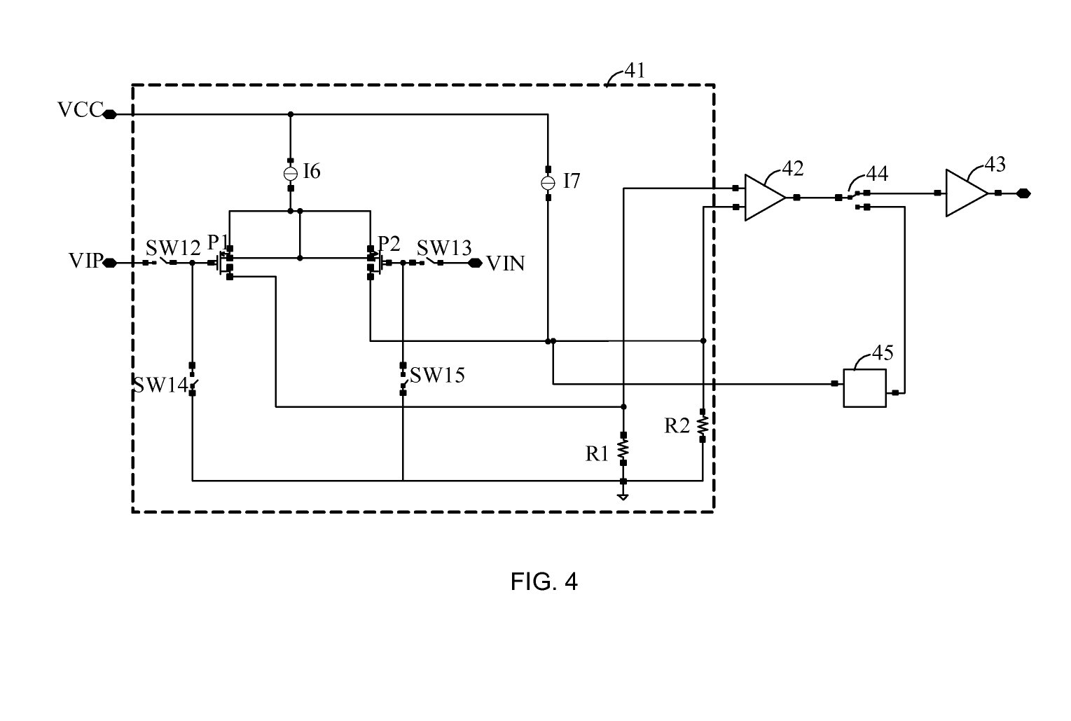

Based on the above discussed current compensation circuit, in an embodiment, an operational amplifier is provided. As shown in FIG. 4, the operational amplifier includes an input stage circuit 41, a gain stage circuit 42, an output stage circuit 43, a two-way switch 44 and a current compensation circuit 45. The input stage circuit 41 is configured to: connect positive and negative inputs of the operational amplifier to ground, when the operational amplifier starts to operate; and receive a positive input signal at the positive input and a negative input signal at the negative input, upon reception of a disconnection signal from the current compensation circuit. The gain stage circuit 42 is configured to connect an positive or negative input of the gain stage circuit 42 to an output of the current compensation circuit 45, and connect an output of the gain stage circuit 42 to the two-way switch 44. The two-way switch 44 is configured to: allow the output of the gain stage circuit 42 to be connected to a detection terminal of the current compensation circuit 45, when the operational amplifier starts to operate; and allow the output of the gain stage circuit 42 to be connected to an input of the output stage circuit 43, upon reception of a disconnection signal from the current compensation circuit 45. The output stage circuit 43 is configured to send out an output signal. The current compensation circuit 45 is configured to: during calibration of a compensation current, generate a digital signal with values varying over time to output different amounts of the compensation current, latch a value of the digital signal, which results in a best compensation current, based on influences of the different amounts of compensation current on a parameter to be calibrated, to complete the calibration; and upon and after completion of the calibration, output the best compensation current based on the digital signal with the latched value, and send the disconnection signal to the input stage circuit 41 and the two-way switch 44.

As shown in FIG. 1, the current compensation circuit 45 includes a digital control circuit 11 and a current compensation array 12. The digital control circuit 11 is configured to: during calibration of a compensation current, deliver a digital signal with values varying over time to the current compensation array 12, and latch a value of the digital signal, which results in a best compensation current, based on influences of different amounts of compensation current on a parameter to be calibrated, to complete the calibration; and upon and after completion of the calibration, continuously deliver a digital signal with the latched value to the current compensation array 12, and send the disconnection signal to the input stage circuit 41 and the two-way switch 44. The current compensation array 12 is configured to: during calibration of the compensation current, output the different amounts of compensation current based on the digital signals with values varying over time; and upon completion of the calibration, output the best compensation current based on the digital signal with the latched value.

As shown in FIG. 4, the input stage circuit 41 includes twelfth to fifteenth switches SW12 to SW15, a sixth current source 16, a seventh current source 17, a first P type metal oxide semiconductor field effect transistor (PMOS) P1 for receiving a positive input signal VIP, a second PMOS P2 for receiving a negative input signal VIN, first and second loads as an input stage load. The twelfth switch SW12 has an end connected to the positive input signal, and another end connected to a gate of the first PMOS P1. The thirteenth switch SW13 has an end connected to the negative input signal, and another end connected to a gate of the second PMOS P2. The fourteenth switch SW14 has an end connected to the gate of the first PMOS P1, and another end connected to ground. The fifteenth switch SW15 has an end connected to the gate of the second PMOS P2, and another end connected to ground. The first PMOS P1 has a source that is connected to a source of the second PMOS P1 and is connected to a power supply VCC via the sixth current source 16, and a drain that is connected to the positive input of the gain stage circuit 42 and is connected to ground via the first load. The second PMOS P2 has a drain that is connected to the negative input of the gain stage circuit 42 and the output of the current compensation circuit 45, is connected to ground via the second load, and is connected to the power supply VCC via the seventh current source 17. The first and second loads may be resistors or current sources. Here, as shown in FIG. 4, a first resistor R1 is used as the first load and a second resistor R2 is used as the second load. When the operational amplifier starts to operate, the twelfth and thirteenth switches SW12 and SW13 are open, and the fourteenth and fifteenth switches SW14 and SW15 are closed. When a disconnection signal is received from the current compensation circuit, the twelfth and thirteenth switches SW12 and SW13 are closed, and the fourteenth and fifteenth switches SW14 and SW15 are open. Accordingly, as shown in FIG. 2, the digital control circuit 11 includes an oscillator 111, a counter 112, a first sampling circuit 113 and an edge detector 114. The oscillator 111 is configured to: output a clock signal; and stop outputting the clock signal upon reception of a stop signal. The counter 112 is configured to: upon reception of the clock signal, start to count cycles of the received clock signal, deliver the digital signal with values varying over time, which are equal to counted values, to the current compensation array 12; and without the clock signal being received, stop counting, and continuously deliver the digital signal with the latched value, which is equal to a final counted value, to the current compensation array 12. The first sampling circuit 113 is configured to: measure the parameter to be calibrated; and send an edge trigger signal to the edge detector 114, when an amount of the compensation current causes the parameter to be calibrated to reach a standard value. The edge detector 114 is configured to send the stop signal to the oscillator 111 and send the disconnection signal to the output stage circuit 41 and the two-way switch 44, upon reception of the edge trigger signal. Accordingly, the current compensation array 12 is configured to output the compensation current based on the digital signal with the value delivered by the counter 112. The current compensation array 12 consists of N parallel current compensation branches, each consisting of a current source for supplying a current and a switch serially connected to the current source, and all of the switches in the N current compensation branches are controlled by the digital signal with the value delivered by the counter. That is, N bits of the digital signal control the respective switches in the N current compensation branches. Here, the N current compensation branches comprise first to Nth current sources respectively, and each of the first to (N−11)th current sources supplies an amount of current that is half of that supplied by its immediate next neighbor. Generally, the first to Nth current sources in the N current compensation branches may supply currents of 20*I . . . 2N−1*I, where the current source in the current compensation branch controlled by the lowest bit supplies a current of 20*I, I is a unit current, and N is a positive integer no less than 2. In the example current compensation circuit as shown in FIG. 2, N is equal to 5, and the 5 current compensation braches includes first to fifth switches SW1 to SW5 respectively and first to fifth current sources I1 to I5.

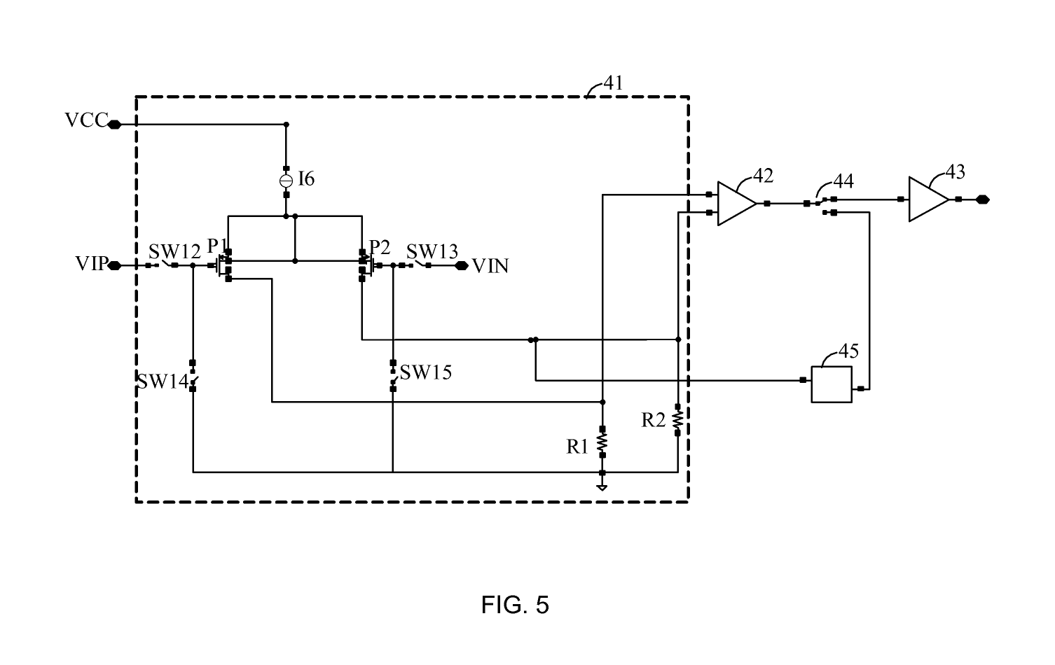

The seventh current source 17 may be omitted from the input stage circuit 41. As shown in FIG. 5, includes twelfth to fifteenth switches SW12 to SW15, a sixth current source 16, a first P type metal oxide semiconductor field effect transistor (PMOS) P1 for receiving a positive input signal VIP, a second PMOS P2 for receiving a negative input signal VIN, first and second loads as an input stage load. The twelfth switch SW12 has an end connected to the positive input signal, and another end connected to a gate of the first PMOS P1. The thirteenth switch SW13 has an end connected to the negative input signal, and another end connected to a gate of the second PMOS P2. The fourteenth switch SW14 has an end connected to the gate of the first PMOS P1, and another end connected to ground. The fifteenth switch SW15 has an end connected to the gate of the second PMOS P2, and another end connected to ground. The first PMOS P1 has a source that is connected to a source of the second PMOS P1 and is connected to a power supply VCC via the sixth current source 16, and a drain that is connected to the positive input of the gain stage circuit 42 and is connected to ground via the first load. The second PMOS P2 has a drain that is connected to the negative input of the gain stage circuit 42 and the output of the current compensation circuit 45, and is connected to ground via the second load. The first and second loads may be resistors or current sources. Here, as shown in FIG. 5, a first resistor R1 is used as the first load and a second resistor R2 is used as the second load. When the operational amplifier starts to operate, the twelfth and thirteenth switches SW12 and SW13 are open, and the fourteenth and fifteenth switches SW14 and SW15 are closed. When a disconnection signal is received from the current compensation circuit, the twelfth and thirteenth switches SW12 and SW13 are closed, and the fourteenth and fifteenth switches SW14 and SW15 are open. Accordingly, as shown in FIG. 3, the digital control circuit 11 includes a digital generator 115 and a second sampling circuit 116. The digital generator 115 is configured to: without a calibration success signal having been received from the second sampling circuit 116, deliver the digital signal with values varying over time to the current compensation array 12 by means of dichotomy; and upon reception of the calibration success signal from the second sampling circuit 116, latch a final value, continuously deliver the digital signal with the latched final value to the current compensation array 12, and send the disconnection signal to the input stage circuit and the two-way switch. The second sampling circuit 116 is configured to: measure the parameter to be calibrated; and send the calibration success signal to the digital generator 115 when an amount of the compensation current causes the parameter to be calibrated to reach a standard value. The current compensation array 12 is configured to output the compensation current based on the digital signal with the value delivered by the digital generator 115. That is, N bits of the digital signal control the respective switches in the N current compensation branches. Here, the N current compensation branches comprise first to Nth current sources respectively, and each of the first to (N−1)th current sources supplies an amount of current that is half of that supplied by its immediate next neighbor. Generally, the first to Nth current sources in the N current compensation branches may supply currents of 20*I . . . 2N−1*I, where the current source in the current compensation branch controlled by the lowest bit supplies a current of 20*I.

Based on the above discussed current compensation circuit, a current compensation method. The method includes the following steps: during calibration of a compensation current, generating a digital signal with values varying over time to output different amounts of compensation current, latching a value of the digital signal, which results in a best compensation current, based on influences of the different amounts of compensation current on a parameter to be calibrated, to complete the calibration; and upon and after completion of the calibration, outputting the best compensation current based on the digital signal with the latched value. The generating may include: using an oscillator to output a clock signal to a counter; using the counter to count cycles of the clock signal received and thus generate the digital signal with values varying over time; and accordingly, using a current compensation array to output the compensation current based on the digital signal with the value delivered by the counter. Alternatively, the generating may include: using a digital generator to deliver the digital signal with values varying over time to a current compensation array by means of dichotomy, when a parameter to be calibrated does not reach a standard value; and accordingly, using the current compensation array to output the compensation current based on the digital signal with the value delivered by the digital generator.

It should be understood that the foregoing description are only preferred embodiments of the disclosure and not intended to limit the patent scope of the disclosure. All changes, equivalent substitution or modifications without departing from the spirit and scope of the application shall be fall into the protection scope of the application.

### Additional Notes

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configured an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A current compensation circuit, comprising:
a digital control circuit configured to:
during calibration of a compensation current, deliver a digital signal with values varying over time to a current compensation array, and latch a value of the digital signal, which results in a best compensation current, based on influences of different amounts of compensation current on a parameter to be calibrated, to complete the calibration; and
upon and after completion of the calibration, continuously deliver a digital signal with the latched value to the current compensation array, wherein the current compensation array is configured to:
during calibration of the compensation current, output the different amounts of compensation current based on the digital signals with values varying over time; and
upon completion of the calibration, output the best compensation current based on the digital signal with the latched value.

2. The current compensation circuit according to claim 1, wherein the digital control circuit comprises an oscillator, a counter, a first sampling circuit and an edge detector,
wherein the oscillator is configured to:
output a clock signal; and
stop outputting the clock signal upon reception of a stop signal, wherein the counter is configured to:
upon reception of the clock signal, start to count cycles of the received clock signal, deliver the digital signal with values varying over time, which are equal to counted values, to the current compensation array; and
without the clock signal being received, stop counting, and continuously deliver the digital signal with the latched value, which is equal to a final counted value, to the current compensation array, wherein the first sampling circuit is configured to:
measure the parameter to be calibrated; and
send an edge trigger signal to the edge detector, when an amount of the compensation current causes the parameter to be calibrated to reach a standard value,
wherein the edge detector is configured to send the stop signal to the oscillator upon reception of the edge trigger signal, and
wherein the current compensation array is configured to output the compensation current based on the digital signal with the value delivered by the counter.

3. The current compensation circuit according to claim 2, wherein the current compensation array consists of N parallel current compensation branches, each consisting of a current source for supplying a current and a switch serially connected to the current source, and all of the switches in the N current compensation branches are controlled by the digital signal with the value delivered by the counter.

4. The current compensation circuit according to claim 3, wherein the N current compensation branches comprise first to Nth current sources respectively, and each of the first to (N−1)th current sources supplies an amount of current that is half of that supplied by its immediate next neighbor.

5. The current compensation circuit according to claim 1, wherein the digital control circuit comprises a digital generator and a second sampling circuit,
wherein the digital generator is configured to:
without a calibration success signal having been received from the second sampling circuit, deliver the digital signal with values varying over time to the current compensation array by means of dichotomy; and
upon reception of the calibration success signal from the second sampling circuit, latch a final value, and continuously delivering the digital signal with the latched final value to the current compensation array,
wherein the second sampling circuit is configured to:
measure the parameter to be calibrated; and
send the calibration success signal to the digital generator when an amount of compensation current causes the parameter to be calibrated to reach a standard value, and
wherein the current compensation array is configured to output the compensation current based on the digital signal with the value delivered by the digital generator.

6. The current compensation circuit according to claim 5, wherein the current compensation array consists of N parallel current compensation branches, each consisting of a current source for supplying a current and a switch serially connected to the current source, and all of the switches in the N current compensation branches are controlled by the digital signal with the value delivered by the digital generator.

7. The current compensation circuit according to claim 6, wherein the N current compensation branches comprise first to Nth current sources respectively, and each of the first to (N−1)th current sources supplies an amount of current that is half of that supplied by its immediate next neighbor.

8. An operational amplifier, comprising an input stage circuit, a gain stage circuit, an output stage circuit, a two-way switch and a current compensation circuit,
wherein the input stage circuit is configured to:
connect positive and negative inputs of the operational amplifier to ground, when the operational amplifier starts to operate; and
receive a positive input signal at the positive input and a negative input signal at the negative input, upon reception of a disconnection signal from the current compensation circuit,
wherein the gain stage circuit is configured to connect an positive or negative input of the gain stage circuit to an output of the current compensation circuit, and connect an output of the gain stage circuit to the two-way switch,
wherein the two-way switch is configured to:
allow the output of the gain stage circuit to be connected to a detection terminal of the current compensation circuit, when the operational amplifier starts to operate; and
allow the output of the gain stage circuit to be connected to an input of the output stage circuit, upon reception of a disconnection signal from the current compensation circuit,
wherein the output stage circuit is configured to send out an output signal, and
wherein the current compensation circuit is configured to:
during calibration of a compensation current, generate a digital signal with values varying over time to output different amounts of the compensation current, latch a value of the digital signal, which results in a best compensation current, based on influences of the different amounts of compensation current on a parameter to be calibrated, to complete the calibration; and
upon and after completion of the calibration, output the best compensation current based on the digital signal with the latched value, and send the disconnection signal to the input stage circuit and the two-way switch.

9. The operational amplifier according to claim 8, wherein the current compensation circuit comprises a digital control circuit and a current compensation array,
wherein the digital control circuit is configured to:
during calibration of the compensation current, deliver the digital signal with values varying over time to the current compensation array, and latch the value of the digital signal, which results in the best compensation current, based on influences of different amounts of compensation current on the parameter to be calibrated, to complete the calibration; and
upon and after completion of the calibration, continuously deliver the digital signal with the latched value to the current compensation array, and send the disconnection signal to the input stage circuit and the two-way switch, and
wherein the current compensation array is configured to:
during calibration of the compensation current, output the different amounts of compensation current based on the digital signals with values varying over time; and
upon completion of the calibration, output the best compensation current based on the digital signal with the latched value.

10. The operational amplifier according to claim 9, wherein the input stage circuit comprises twelfth to fifteenth switches, a sixth current source, a seventh current source, a first P type metal oxide semiconductor field effect transistor (PMOS) for receiving the positive input signal, a second PMOS for receiving the negative input signal, first and second loads as an input stage load,
wherein the twelfth switch has an end connected to the positive input signal, and another end connected to a gate of the first PMOS,
wherein the thirteenth switch has an end connected to the negative input signal, and another end connected to a gate of the second PMOS,
wherein the fourteenth switch has an end connected to the gate of the first PMOS, and another end connected to ground,
wherein the fifteenth switch has an end connected to the gate of the second PMOS, and another end connected to ground,
wherein the first PMOS has a source that is connected to a source of the second PMOS and is connected to a power supply via the sixth current source, and a drain that is connected to the positive input of the gain stage circuit and is connected to ground via the first load, and
wherein the second PMOS has a drain that is connected to the negative input of the gain stage circuit and the output of the current compensation circuit, is connected to ground via the second load, and is connected to the power supply via the seventh current source.

11. The operational amplifier according to claim 10, wherein the digital control circuit comprises an oscillator, a counter, a first sampling circuit and an edge detector,
wherein the oscillator is configured to:
output a clock signal; and
stop outputting the clock signal upon reception of a stop signal,
wherein the counter is configured to:
upon reception of the clock signal, start to count cycles of the received clock signal, deliver the digital signal with values varying over time, which are equal to counted values, to the current compensation array; and
without the clock signal being received, stop counting, and continuously deliver the digital signal with the latched value, which is equal to a final counted value, to the current compensation array, wherein the first sampling circuit is configured to:
measure the parameter to be calibrated; and
send an edge trigger signal to the edge detector, when an amount of the compensation current causes the parameter to be calibrated to reach a standard value,
wherein the edge detector is configured to send the stop signal to the oscillator and send the disconnection signal to the input stage circuit and the two-way switch, upon reception of the edge trigger signal, and
wherein the current compensation array is configured to output the compensation current based on the digital signal with the value delivered by the counter.

12. The operational amplifier according to claim 11, wherein the current compensation array consists of N parallel current compensation branches, each consisting of a current source for supplying a current and a switch serially connected to the current source, and all of the switches in the N current compensation branches are controlled by the digital signal with the value delivered by the counter.

13. The operational amplifier according to claim 12, wherein the N current compensation branches comprise first to Nth current sources respectively, and each of the first to (N−1)th current sources supplies an amount of current that is half of that supplied by its immediate next neighbor.

14. The operational amplifier according to claim 9, wherein the input stage circuit comprises twelfth to fifteenth switches, a sixth current source, a first P type metal oxide semiconductor field effect transistor (PMOS) for receiving the positive input signal, a second PMOS for receiving the negative input signal, first and second loads as an input stage load,
wherein the twelfth switch has an end connected to the positive input signal, and another end connected to a gate of the first PMOS,
wherein the thirteenth switch has an end connected to the negative input signal, and another end connected to a gate of the second PMOS,
wherein the fourteenth switch has an end connected to the gate of the first PMOS, and another end connected to ground,
wherein the fifteenth switch has an end connected to the gate of the second PMOS, and another end connected to ground,
wherein the first PMOS has a source that is connected to a source of the second PMOS and is connected to a power supply via the sixth current source, and a drain that is connected to the positive input of the gain stage circuit and is connected to ground via the first load, and
wherein the second PMOS has a drain that is connected to the negative input of the gain stage circuit and the output of the current compensation circuit, and is connected to ground via the second load.

15. The operational amplifier according to claim 14, wherein the digital control circuit comprises a digital generator and a second sampling circuit,
wherein the digital generator is configured to:
without a calibration success signal having been received from the second sampling circuit, deliver the digital signal with values varying over time to the current compensation array by means of dichotomy; and
upon reception of the calibration success signal from the second sampling circuit, latch a final value, continuously deliver the digital signal with the latched final value to the current compensation array, and send the disconnection signal to the input stage circuit and the two-way switch,
wherein the second sampling circuit is configured to:
measure the parameter to be calibrated; and
send the calibration success signal to the digital generator when an amount of the compensation current causes the parameter to be calibrated to reach a standard value, and
wherein the current compensation array is configured to output the compensation current based on the digital signal with the value delivered by the digital generator.

16. The operational amplifier according to claim 15, wherein the current compensation array consists of N parallel current compensation branches, each consisting of a current source for supplying a current and a switch serially connected to the current source, and all of the switches in the N current compensation branches are controlled by the digital signal with the value delivered by the digital generator.

17. The operational amplifier according to claim 16, wherein the N current compensation branches comprise first to Nth current sources respectively, and each of the first to (N−1)th current sources supplies an amount of current that is half of that supplied by its immediate next neighbor.

18. A current compensation method, comprising:
during calibration of a compensation current, generating a digital signal with values varying over time to output different amounts of compensation current, latching a value of the digital signal, which results in a best compensation current, based on influences of the different amounts of compensation current on a parameter to be calibrated, to complete the calibration; and
upon and after completion of the calibration, outputting the best compensation current based on the digital signal with the latched value.

19. The current compensation method according to claim 18, wherein the generating comprises:
using an oscillator to output a clock signal to a counter;
using the counter to count cycles of the clock signal received and thus generate the digital signal with values varying over time; and
accordingly, using a current compensation array to output the compensation current based on the digital signal with the value delivered by the counter.

20. The method of current compensation according to claim 18, wherein the generating comprises:
using a digital generator to deliver the digital signal with values varying over time to a current compensation array by means of dichotomy, when a parameter to be calibrated does not reach a standard value; and
accordingly, using the current compensation array to output the compensation current based on the digital signal with the value delivered by the digital generator.
